(19) United States
(12) Patent Application Publication
(10) Pub. No.: US 2013/0269599 A1
(43) Pub. Date: Oct. 17, 2013

(54) Methods and Apparatus for Continuous Pressure Control Processing

(71) Applicants: Chien-Feng Lin, Zhudong Township (TW); Tsung-Hsun Yu, Hsin-Chu (TW)

(72) Inventors: Chien-Feng Lin, Zhudong Township (TW); Tsung-Hsun Yu, Hsin-Chu (TW)

(73) Assignee: TAIWAN SEMICONDUCTOR MANUFACTURING COMPANY, LTD., Hsin-Chu (TW)

(21) Appl. No.: 13/446,179

(22) Filed: Apr. 13, 2012

(51) Int. Cl. C30B 25/16; C30B 25/08

(52) U.S. Cl. 117/88; 118/733

(57) ABSTRACT

Apparatus and method for continuous pressure control in a process chamber. An apparatus includes a process chamber configured to receive a wafer; at least one pump coupled to the process chamber for maintaining pressure in the process chamber; an inlet for receiving reactive gasses into the process chamber; and a pressure control valve positioned between the at least one pump and configured to seal the process chamber to control the pressure in the process chamber. A method includes disposing at least one semiconductor wafer into a process chamber that is coupled to a pump for maintaining a sub-atmospheric pressure within the process chamber; introducing reactive process gasses into the process chamber; using a pressure control valve, at least partially sealing the process chamber; and increasing the pressure within the process chamber while exposing the semiconductor wafer to the process gasses to form epitaxial material. Additional embodiments are disclosed.

### TECHNICAL FIELD

The present invention relates to a process chamber for semiconductor processing and more particularly to methods and apparatus for continuous pressure control during epitaxial deposition in advanced semiconductor processes.

### BACKGROUND

A current common requirement for an electronic circuit and particularly for electronic circuits manufactured as integrated circuits in semiconductor processes is epitaxial deposition of materials. As is known in the art, the use of differing semiconductor materials can create beneficial stress and strain in the channel regions of MOS transistor devices, which can result in increased carrier mobility and thus enhanced transistor performance. In one application, silicon substrates may receive a deposition of a material having a larger lattice constant such as silicon germanium (SiGe) in source and drain regions adjacent a channel region. The change in lattice constants can exert a beneficial stress or strain on the channel region, which can enhance carrier mobility. Other process steps may also use epitaxial SiGe materials. The epitaxial material may be deposited in a chemical vapor deposition (CVD) process chamber at a reduced pressure or near vacuum. The epitaxial material may be a layer, or selective epitaxial growth in certain areas, such as within source/drain regions of MOS transistors.

Current semiconductor process tools provide a process chamber for CVD epitaxy, but what is needed is a continuous pressure control apparatus and methods for providing pressure control during processing over a wide range of pressures.

### BRIEF DESCRIPTION OF THE FIGURES

For a more complete understanding of the present invention, and the advantages thereof, reference is now made to the following descriptions taken in conjunction with the accompanying drawings, in which:

FIG. 1 illustrates a CVD process system for use with the embodiments;

FIG. 2 illustrates in a plan view a valve embodiment;

FIG. 3 illustrates a pressure control valve incorporating the valve embodiment of FIG. 2;

FIG. 4 illustrates another plan view of a valve embodiment including a seal;

FIG. 5 illustrates in a side view the valve embodiment of FIG. 4;

FIG. 6 illustrates in a plan view a portion of a valve embodiment;

FIG. 7 illustrates in a cross section a view of an alternative valve embodiment;

FIG. 8 illustrates in a graph an example pressure rise plotted versus time for a system incorporating an embodiment; and

FIG. 9 illustrates in a flow diagram a method embodiment.

The drawings, schematics and diagrams are illustrative and not intended to be limiting, but are examples of embodiments of the invention, are simplified for explanatory purposes, and are not drawn to scale.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

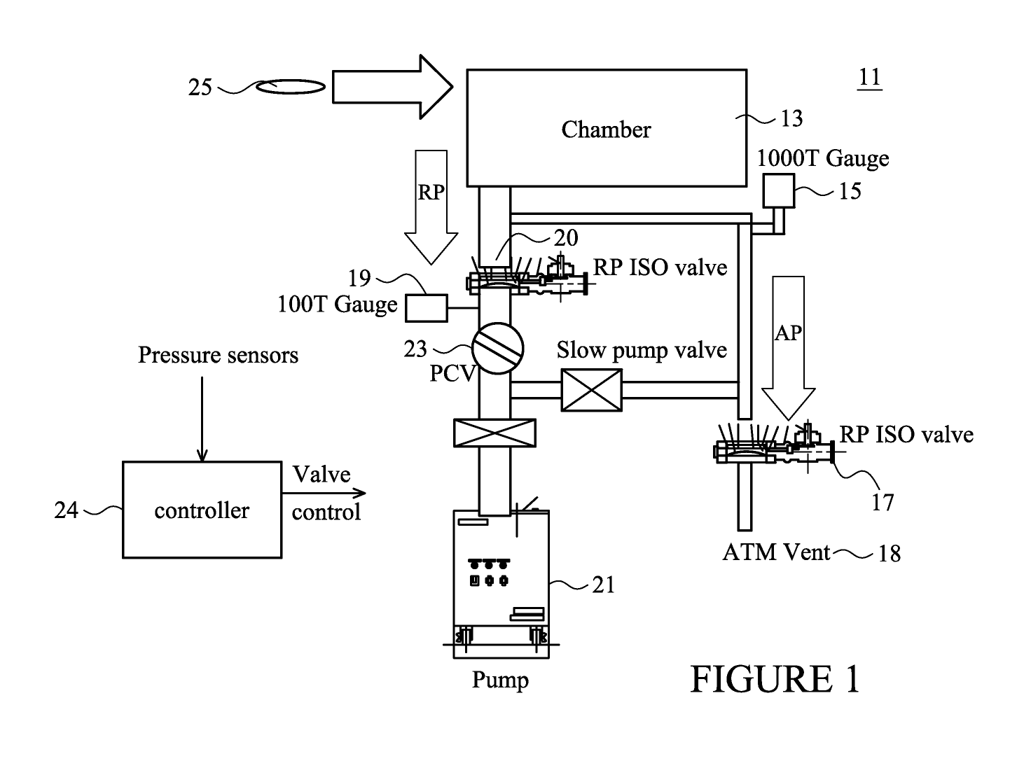

FIG. 1 depicts as a non-limiting example, a CVD system which may incorporate the embodiments. In FIG. 1, a process tool 11 which may, for example, a single wafer epitaxial reactor such as an Epsilon series epitaxial production reaction available from ASM, at ASM America, 3440 E. University Drive, Phoenix, Ariz., USA 85034-7200. The embodiments may be applied to any process chamber tool, and may apply to multiple wafer tools or multiple chamber tools as well as single chamber, single wafer tools. The embodiments are not limited to any particular process tool or equipment.

In FIG. 1, a reaction chamber 13 is shown and receives a wafer 25 for processing. While not illustrated in FIG. 1 for simplicity, a wafer loading system which may include a cassette for receiving wafers, a cassette for removing processed wafers, a vacuum load lock for transferring wafers, and a robot arm for handling wafers, may be provided and used to present a new wafer for processing into the reaction chamber 13. A valve 20 is shown for receiving reactive process gasses. This valve allows the reactive process gasses to enter the chamber in a controlled manner. Epitaxial growth of SiGe may be performed as a chemical vapor deposition (CVD) process and deposition may be performed at an elevated temperature. Typically a so-called “low temperature” approach is used to control previously deposited material profiles and prevent out diffusion of implanted dopants. The pressure used is at a reduced pressure that is reduced below atmospheric pressure. A gauge 19 monitors pressures below 100 Torr. A pump 21 provides a way to control the pressure in the chamber. A gauge 15 monitors pressures up to 1000 Torr (atmospheric pressure, or 1 atmosphere, is 760 Torr). A valve 17 enables the atmosphere to enter the chamber, and a vent 18 allows the chamber to vent to the atmosphere.

During processing, reactive process gasses may be introduced into the chamber 13 for epitaxial growth of the SiGe material. These gasses may include, for example, germane, silane, dichlorosilane, silicon tetrachloride, and hydrogen chloride. Other gasses may be used to clean or purge the chamber, and the wafer. SiGe epitaxial growth is desirably performed with low or no oxygen content in the environment. The gasses may flow in a laminar flow over the surface of the wafer in the chamber, which rests on a support or susceptor within the chamber.

During processing, it is desirable to change the pressure in the chamber. For example, it might be desirable to begin with the chamber at a reduced pressure below 1 atmosphere, below 100 Torr, or even less than 1 Torr, and then increase the pressure as the reactive process gasses flow to several millitorr, several Torr or hundreds of Torr. The pressure control valve, 23, in the diagram, would be used to control this pressure in conjunction with pump 21. The reduced pressure can be monitored by gauge 19 for example. A controller 24 may sense the pressure and control the valves, using a valve control output. The controller may be a computer, microprocessor, PC, or the like, and may include automated programming or manual monitoring.

In prior approaches, the pressure control valve is formed in a manner that includes a gap. This is done in part to prevent the occurrence of metal sparks when it is operated. A metal such as stainless steel may be used to form a flapper valve that is a circular plate or disc. The valve can be rotated with a housing to form a closed valve, or opened fully to form an open shaft. The gasses used in the process chamber may be flammable. A gap is formed between the valve and the housing to prevent sparks from occurring when the valve is closed, to that there is no metal-to-metal contact. When the valve is closed, the pressure remains low until the reaction byproducts of the gasses circulating in the system deposit on the valve sufficiently to form a seal. This process is slow, and inexact, so that the chamber pressure is not easily controlled. A long delay time is needed after the valve is closed, to reach a desired pressure. This delay reduces throughput. Also, the delay is not easily predicted as the “seal” is formed by deposition of byproducts of the epitaxial process.

In the embodiments, it is desired to provide continuous pressure control and to allow the chamber to have a variety of pressures under control of the pressure control valve. Further, using the embodiments, the chamber may be sealed completely when desired and without delay.

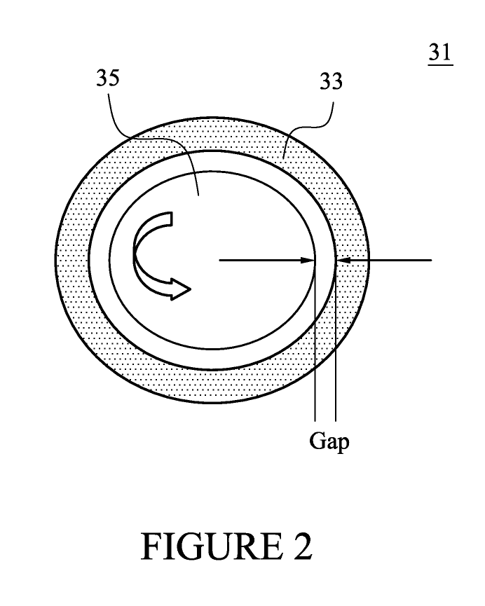

FIG. 2 depicts a valve portion 31 of an embodiment pressure control valve. In this embodiment, a seal portion is omitted for explanation. A gap of, for example, 0.05 millimeters, is shown between the outer edge of the flapper 35, which is rotatably mounted in the housing 33, and the inner portion of the housing. The flapper is circular and of similar diameter to the internal shaft of the housing. In the embodiments, the gap will be sealed as described below.

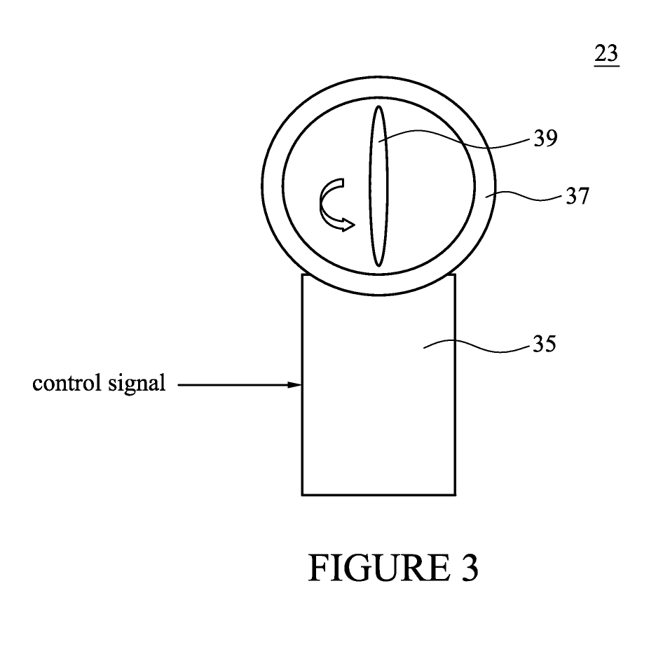

FIG. 3 depicts a pressure control valve 23 in an embodiment. A servo motor portion 35 is coupled to valve which has a valve housing 37 and a flapper valve 39 that is rotatably mounted within the housing. A control signal is received by the servo motor 35 and the valve rotates in response to the control signal.

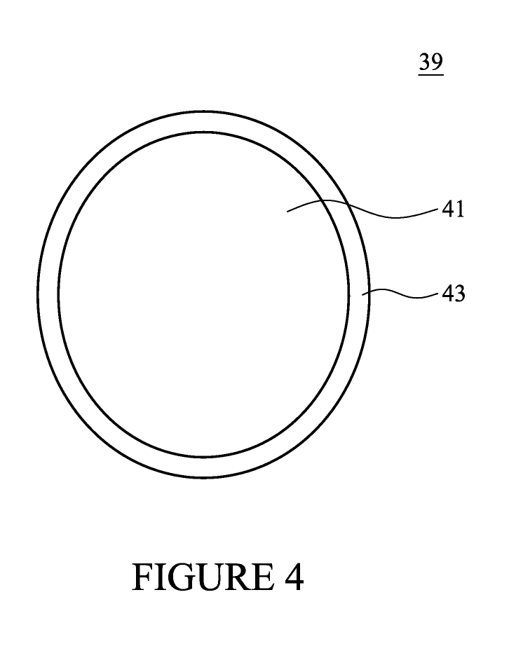

FIG. 4 depicts in a plan view a flapper valve 39 of the embodiments. A seal 43 is shown disposed around the outer edge of the valve body 41. The valve body 41 may be a disc or circular plate of stainless steel or other materials that are compatible with the process gasses and materials used in the system. A seal 43 is provided. In some embodiments seal 43 is an “O” ring. The seal may be of an elastomeric material that is of sufficient diameter to form a pressure seal with the inner surface of the valve housing 37 when the valve is closed. In one embodiment, a fluorinated rubber is used for the seal. The inner surface of the valve housing may include a stainless steel liner. Alternatively, the entire valve housing may be of stainless steel. Other materials may also be used.

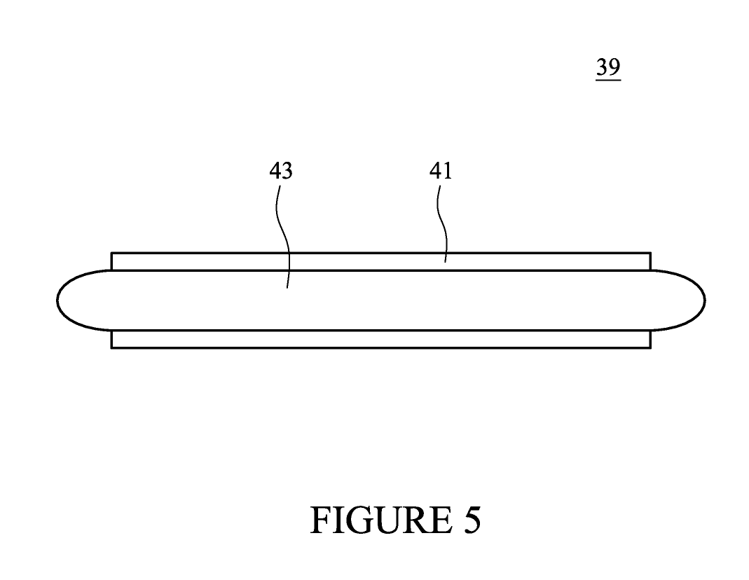

FIG. 5 depicts in a side view the flapper valve 39. The seal 43 is shown disposed on the outer edge of the flapper valve body 41.

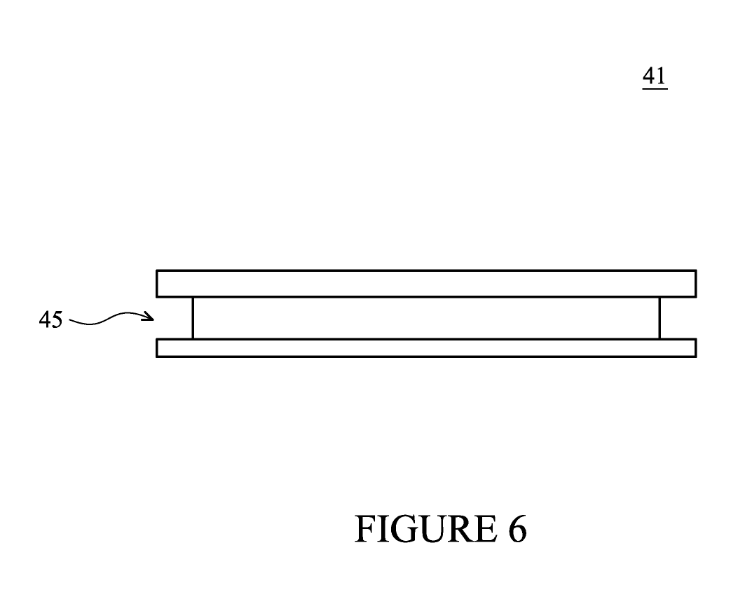

FIG. 6 depicts the flapper valve body 41 in a side view without the seal, and depicts a flange 45 that is formed on the edge of the flapper valve body 41 to receive the seal 43. As described above the seal may be in an “O” ring form. The seal will have sufficient width to fill any gap between the edge of the flapper valve body 41 and the inner surface of the valve housing, and, will seat in the flange 45.

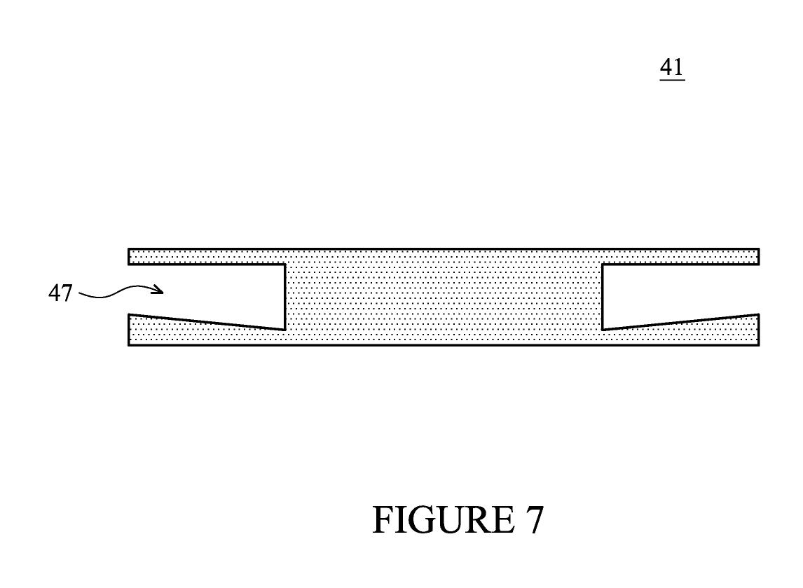

FIG. 7 depicts in an alternative embodiment another shape for the flange in the flapper valve body 41. In this alternative, a flange 45 has a sloped side on one surface and a straight side on the other surface, to better receive the seal 43 (not shown in this view). This shape tends to hold the seal in place. Again the valve body 41 may be of stainless steel, for example.

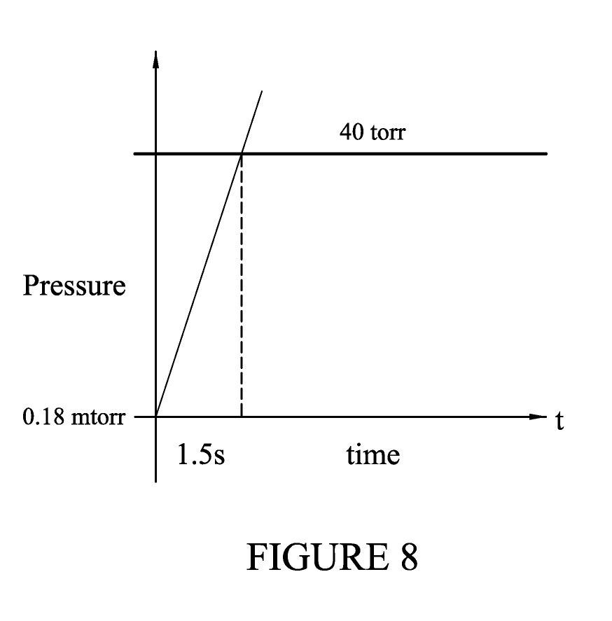

FIG. 8 depicts a pressure v. time graph of a pressure increase using the pressure control valve of the embodiments in a system and illustrating the pressure increase over time when the valve is closed. At time 0, the pressure observed is 0.18 millitorr. After the pressure control valve is closed, the pressure increased to 40 torr in only 1.5 seconds. In contrast, using a pressure control valve of the prior approach, the time to reach 40 torr was over 10 seconds, and approached 11 seconds. Thus the system throughput in the prior art approach is greatly decreased by this long wait time each time the pressure was to be increased. Further, use of the pressure control valve of the embodiments with a controller provides continuous pressure control in the chamber, because the pressure control valve can be partially or completely closed and instantly change the pressure. This is in great contrast to the prior approach, where the reaction byproducts must deposit on the valve edges to increase the pressure.

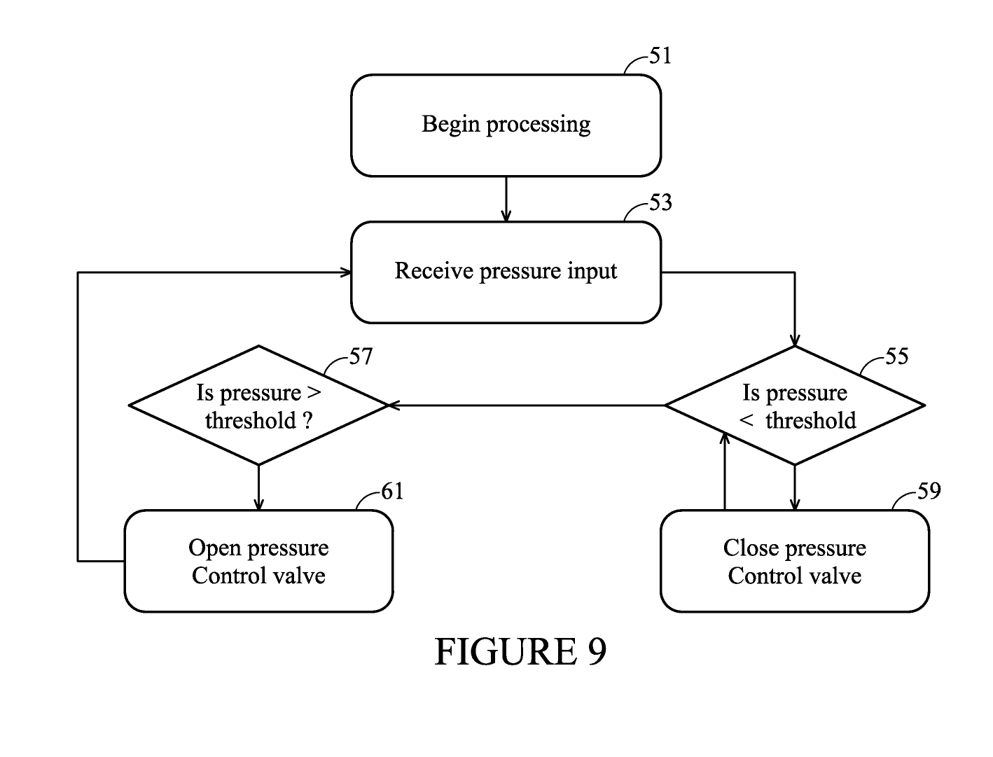

FIG. 9 depicts in a flow diagram a pressure control method embodiment. In FIG. 9, a process begins at step 51. In an example, a semiconductor wafer may be introduced into a process chamber at an initial reduced pressure, for example. At step 53, a controller such as shown in the example of FIG. 1, may receive a pressure sensor input. A comparison is made at step 55. If the pressure is below a desired threshold, the pressure control valve may be closed to seal the chamber. The inlet receiving reactive process gasses will continue to flow gasses into the chamber, and the pressure within the process chamber will increase. Because the pressure control valve of the embodiments immediately seals the chamber, the pressure will rapidly increase as seen in FIG. 8. The method continues at step 55 again checking the pressure. If the pressure becomes equal to or greater than the threshold, the method transitions to step 47. Again the pressure is compared and if it is greater than a threshold pressure, the method transitions to step 61 where the pressure control valve may be partially opened. The method continues by transitioning to step 53, and so a continuous pressure control loop is established.

The embodiments may be implemented by modifying existing equipment in process chamber tools to add the seal embodiments to the pressure control valve. Alternatively, a new pressure control valve may be installed, replacing the existing equipment, and including a new valve housing with the seal of the embodiments. The embodiments are compatible with existing process flows and controllers, and no change to materials or the semiconductor wafers is required to use the embodiments and attain the advantages of the embodiments.

In an embodiment, an apparatus, comprises a process chamber configured to receive a wafer; at least one pump coupled to the process chamber for maintaining pressure in the process chamber; an inlet for receiving reactive gasses into the process chamber; and a pressure control valve positioned between the at least one pump and configured to seal the process chamber to control the pressure in the process chamber. In a further embodiment, in the above apparatus, the pump maintains a pressure below atmospheric pressure in the process chamber. In another embodiment, in the above apparatus, the pressure control valve is coupled to a control unit that changes an opening of the pressure control valve responsive to a pressure gauge. In still a further embodiment, in the above apparatus the pressure control valve comprises a circular flapper valve rotatably mounted in a valve body with an internal opening, the circular flapper valve having a seal on an outer edge that meets an inner surface of the internal opening of the valve body when the circular flapper valve is moved into a closed position. In yet another embodiment, the circular flapper valve further comprises a flange machined into an outer edge for receiving the seal. In a further embodiment, in the above apparatus the circular flapper valve further comprises a circular plate having a maximum diameter that is less than a smallest diameter of the internal opening by at least 0.04 millimeters. In still a further embodiment, the seal is an O ring shape. In yet another embodiment the O ring has a maximum diameter that is about equal to a smallest diameter of the internal opening. In still another embodiment the seal is an elastomeric seal. In yet another embodiment the elastomeric seal comprises fluorinated rubber.

In a further embodiment, in the above apparatus the process chamber receives reactive gasses including at least one selected from the group consisting essentially of germane, silane, dichlorosilane, silicon tetrachloride, and hydrogen chloride. In still another embodiment, the pressure within the process chamber may be less than 1 millitorr. In yet another embodiment the pressure within the process chamber may be several torr.

In an embodiment, a semiconductor processing tool for epitaxial growth includes a process chamber for receiving at least one semiconductor wafer on a wafer support, the process chamber sealed to maintain a sub-atmospheric pressure; a pump coupled to the process chamber for maintaining the pressure within the process chamber; a pressure control valve coupled between the pump and the process chamber and having a seal for sealing the process chamber; a controller coupled to the pressure control valve and to a pressure gauge, for selectively closing the pressure control valve responsive to the pressure gauge; and an inlet valve for receiving reactive process gasses to form epitaxial material on the semiconductor wafer. In a further embodiment, in the above semiconductor processing tool, the pressure control valve comprises a circular flapper valve rotatably mounted in a valve body with an internal opening, the circular flapper valve having a seal that meets inner walls of the internal opening of the valve body when the circular flapper valve is moved into a closed position.

In still a further embodiment the circular flapper valve further comprises a flange on an outer edge of the circular flapper valve for receiving the seal. In yet another embodiment, the seal is an elastomeric seal. In a further embodiment, the elastomeric seal comprises fluorinated rubber.

In another embodiment, a method includes disposing at least one semiconductor wafer into a process chamber that is coupled to a pump for maintaining a sub-atmospheric pressure within the process chamber; establishing a first reduced pressure in the process chamber; introducing reactive process gasses into the process chamber; using a pressure control valve coupled between the pump and the process chamber, at least partially sealing the process chamber; and increasing the pressure within the process chamber while exposing the semiconductor wafer to the process gasses to form epitaxial material. In still a further embodiment, in the above method introducing reactive process gasses into the process chamber further comprises introducing a reactive process gas selected from group consisting essentially of germane, silane, dichorlosilane, and hydrogen chloride.

Although exemplary embodiments of the present invention and its advantages have been described in detail, it should be understood that various changes, substitutions and alterations can be made herein without departing from the spirit and scope of the invention as defined by the appended claims. For example, it will be readily understood by those skilled in the art that the methods may be varied while remaining within the scope of the present invention.

Moreover, the scope of the present application is not intended to be limited to the particular embodiments of the methods and steps described in the specification. As one of ordinary skill in the art will readily appreciate from the disclosure of the present invention, processes, or steps, presently existing or later to be developed, that perform substantially the same function or achieve substantially the same result as the corresponding embodiments described herein may be utilized according to the present invention. Accordingly, the appended claims are intended to include within their scope such processes or steps.

What is claimed is:

1. An apparatus, comprising:
a process chamber configured to receive a wafer;
at least one pump coupled to the process chamber for maintaining pressure in the process chamber;
an inlet for receiving reactive gasses into the process chamber; and
a pressure control valve positioned between the at least one pump and configured to seal the process chamber to control the pressure in the process chamber.

2. The apparatus of claim 1, wherein the pump maintains a pressure below atmospheric pressure in the process chamber.

3. The apparatus of claim 1, wherein the pressure control valve is coupled to a control unit that changes an opening of the pressure control valve responsive to a pressure gauge.

4. The apparatus of claim 1, wherein the pressure control valve comprises a circular flapper valve rotatably mounted in a valve body with an internal opening, the circular flapper valve having a seal on an outer edge that meets an inner surface of the internal opening of the valve body when the circular flapper valve is moved into a closed position.

5. The apparatus of claim 4, wherein the circular flapper valve further comprises a flange in the outer edge for receiving the seal.

6. The apparatus of claim 4, wherein the circular flapper valve further comprises a circular plate having a maximum diameter that is less than a smallest diameter of the internal opening by at least 0.04 millimeters.

7. The apparatus of claim 4, wherein the seal is an O ring shape.

8. The apparatus of claim 7, wherein the O ring has a maximum diameter that is about equal to a smallest diameter of the internal opening.

9. The apparatus of claim 4, wherein the seal is an elastomeric seal.

10. The apparatus of claim 9, wherein the elastomeric seal comprises fluorinated rubber.

11. The apparatus of claim 1, wherein the process chamber receives reactive gasses including at least one selected from the group consisting essentially of germane, silane, dichlorosilane, silicon tetrachloride, and hydrogen chloride.

12. The apparatus of claim 1, wherein the pressure within the process chamber may be less than 1 millitorr.

13. The apparatus of claim 1, wherein the pressure within the process chamber may be several torr.

14. A semiconductor processing tool for epitaxial growth, comprising:
a process chamber for receiving at least one semiconductor wafer on a wafer support, the process chamber sealed to maintain a sub-atmospheric pressure;
a pump coupled to the process chamber for maintaining the pressure within the process chamber;
a pressure control valve coupled between the pump and the process chamber and having a seal for sealing the process chamber;
a controller coupled to the pressure control valve and to a pressure gauge, for selectively closing the pressure control valve responsive to the pressure gauge; and
an inlet valve for receiving reactive process gasses to form epitaxial material on the semiconductor wafer.

15. The semiconductor processing tool of claim 14, wherein the pressure control valve comprises a circular flapper valve rotatably mounted in a valve body with an internal opening, the circular flapper valve having a seal that meets inner walls of the internal opening of the valve body when the circular flapper valve is moved into a closed position.

16. The semiconductor processing tool of claim 15, wherein the circular flapper valve further comprises a flange on an outer edge of the circular flapper valve for receiving the seal.

17. The semiconductor processing tool of claim 15, wherein the seal is an elastomeric seal.

18. The semiconductor processing tool of claim 17, wherein the elastomeric seal comprises fluorinated rubber.

19. A method for epitaxial growth, comprising:
disposing at least one semiconductor wafer into a process chamber that is coupled to a pump for maintaining a sub-atmospheric pressure within the process chamber;
establishing a first reduced pressure in the process chamber;
introducing reactive process gasses into the process chamber;
using a pressure control valve coupled between the pump and the process chamber, at least partially sealing the process chamber; and
increasing the pressure within the process chamber while exposing the semiconductor wafer to the process gasses to form epitaxial material.

20. The method of claim 19, wherein introducing reactive process gasses into the process chamber further comprises introducing a reactive process gas selected from group consisting essentially of germane, silane, dichorlosilane, and hydrogen chloride.
